(19) United States
(12) Patent Application Publication
(10) Pub. No.: US 2009/0286165 A1
(43) Pub. Date: Nov. 19, 2009

(54) HOLOGRAM LAMINATE, HOLOGRAM COPY METHOD, AND HOLOGRAM PRODUCING METHOD

(75) Inventor: Yoshihiro Sugiura, Shizuoka (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/435,883

(22) Filed: May 5, 2009

(30) Foreign Application Priority Data
May 16, 2008 (JP) 2008-129703
Oct. 17, 2008 (JP) 2008-268193

(51) Int. Cl. G03F 7/00; G03F 7/11

(52) U.S. Cl. 430/2; 359/3

(57) ABSTRACT

A hologram laminate is provided. The hologram laminate includes a hologram record layer, and a surface protection layer. The hologram record layer is made of a photosensitive material. The surface protection layer is coated on one surface of the hologram record layer. The surface protection layer is made of an energy ray curing resin.

### CROSS REFERENCES TO RELATED APPLICATIONS

The present application claims priority to that disclosed in Japanese Priority Patent Application JP 2008-129703 filed in the Japan Patent Office on May 16, 2008 and Japanese Priority Patent Application JP 2008-268193 filed in the Japan Patent Office on Oct. 17, 2008, the entire content of which are hereby incorporated by reference.

### BACKGROUND

The present disclosure relates to a hologram laminate, a hologram copy method, and a hologram producing method applicable to a Lippmann hologram.

Holograms that can be displayed in 3D have been widely used to determine whether or not credit cards are genuine or fake. At present, emboss type holograms on which an interference film is unevenly formed have been widely used. However, emboss type holograms tend to be easily forged. In contrast, Lippmann type holograms on which an interference film is formed as changes of the refractive index of the internal film are very difficult to be forged because a record image is created using advanced techniques and record materials are difficult to obtain.

A Lippmann type hologram is produced mainly by a content production step including capturing images, obtaining computer graphic images, and editing the obtained images, a hologram master production step, and a copy (mass production) step. A plurality of images obtained by the image editing step are converted into rectangular images by for example a cylinder lens. Interference flings of object illumination light of an image and reference light are successively recorded as rectangular hologram elements on a hologram record medium. As a result, a master is produced. A hologram record medium is brought into contact with the master and laser light is irradiated thereto. As a result, the hologram is copied.

In the hologram, image information obtained by successively imaging an object from laterally different observation points are laterally and successively recorded as rectangular hologram elements. Thus, when the observer views this hologram with both his or her eyes, two-dimensional images that the left and right eyes see are slightly different. As a result, the observer feels a parallax. Thus, a three-dimensional image is reproduced.

As described above, when rectangular hologram elements are successively recorded, a horizontal parallax only (HPO) hologram is produced. An HPO type hologram can be printed in a short time with high image quality. Depending on a recording system, a hologram having a vertical parallax can be produced. A hologram having parallaxes both in the horizontal and vertical directions is referred to as a full parallax (FP) type hologram.

A hologram record medium that is used for copying (hereinafter referred to as a hologram laminate) is disclosed in Japanese Patent Application Laid-Open Publication No. HEI 9-090857 as shown in FIG. 1. The structure described in Japanese Patent Application Laid-Open Publication No. HEI 9-090857 does not have a blocking layer 106 and a surface protection layer 108.

In FIG. 1, on a separator layer denoted by the lowest two-dashed line (also called a release paper, a release film, a cover sheet, etc.) 101, an adhesion layer 102, a black sheet 103, an adhesion layer 104, a hologram record layer 105 made of a photosensitive material, for example, a photopolymer, a blocking layer (hard coat, etc.) 106, a support film 107, and a surface protection layer (hard coat) 108 are successively formed. The separator layer 101 is made, for example, of polyethylene terephthalate (PET).

The support film 107 is made, for example, of PET, polycarbonate (PC), or polymethyl methacrylate (PMMA). Since the surface hardness of the support film 107 is low and subject to be easily scratched, it is necessary to perform a hard coat treatment for the front surface and form a hard coat 108 thereon. In addition, it is difficult to thinly form the support film 107 with a thickness of around several μm to several ten μm.

To maintain the quality of an image recorded on the hologram record layer 105, it is necessary for the support film 107 to have a sufficiently low birefringence. In addition, it is preferred that the refractive index of the support film 107 be the same as that of the hologram record layer 105.

Since the support film 107 is chemically damaged depending on a component of the photosensitive material (chemical attack) for use, it is necessary to dispose a blocking layer (hard coat, etc.) between the hologram record layer 105 and the support film 107.

After the photosensitive material is completely polymerized, it is necessary to coat the adhesion layer 104 on the front surface of the hologram record layer 105. Thus, while the photosensitive material has not been exposed or a monomer component resides, it is difficult to form an adhesion layer.

Because of the foregoing reason, the structure shown in FIG. 1 can be accomplished. However, such a hologram laminate is as thick as 100 μm even excluding the separator layer 101. If a hologram laminate is adhered on a product, it is desired that the total thickness be as small as possible. In addition, there was a problem that the production steps would become complicated and the fabrication cost would rise. In addition, when a copy is produced by laser exposure, if an air layer is formed between a hologram master and a hologram laminate, its refractive index varies. Thus, it is difficult to produce copies of the master. To solve such a problem, it is necessary to perform a step of coating optical contact liquid on the interface of the master and the hologram laminate such that air is removed therebetween and the master and the hologram laminate are brought into contact. However, it is difficult to perfectly prevent air from entering and the optical contact liquid is harmful to the human body. Thus, there is a problem to use optical contact liquid.

In view of the foregoing, it would be desirable to provide a hologram laminate, a hologram copy method, and a hologram producing method that can solve such a problem.

### SUMMARY

According to an embodiment, there is provided a hologram laminate, including a hologram record layer, and a surface protection layer. The hologram record layer is made of a photosensitive material. The surface protection layer is coated on one surface of the hologram record layer. The surface protection layer is made of an energy ray curing resin.

It is preferred that an adhesive agent layer be coated on another surface of the hologram record layer.

It is preferred that the adhesive agent layer be black.

It is preferred that a separator layer be coated on the adhesive agent layer.

According to an embodiment, there is provided a hologram laminate, including a hologram record layer, a surface protection layer, and a blocking layer. The hologram record layer is made of a photosensitive material. The surface protection layer is coated on one surface of the hologram record layer. The blocking layer is coated on another surface of the hologram record layer. The surface protection layer and the blocking layer are made of an energy ray curing resin.

It is preferred that an adhesive agent layer be further coated on the blocking layer.

It is preferred that the adhesive agent layer be black.

It is preferred that a separator layer be coated on the adhesive agent layer.

According to an embodiment, there is provided a method of copying a hologram. A photosensitive material is coated on an energy ray curing resin. The photosensitive material and a master having a hologram record layer on which a hologram has been recorded are oppositely placed. The photosensitive material is brought into contact with the master. Laser light is irradiated from the energy ray curing resin side to the photosensitive material and the master that have been brought into contact with each other.

According to an embodiment, there is provided a method of copying a hologram. A photosensitive material having a predetermined thickness is coated on an energy ray curing resin. A hologram is copied by bringing the photosensitive material in contact with a master having a hologram record layer on which a hologram has been recorded and irradiating laser light from the energy ray curing resin side to the photosensitive material and the master that have been brought into contact with each other. The energy ray curing resin coated on the photosensitive material is cured.

It is preferred that a first position at which the coating step is performed, a second position at which the copying step is performed, and a third position at which the curing step is performed be connected in line by conveying means.

According to an embodiment, there is provided a method of copying a hologram. A photosensitive material having a predetermined thickness is coated on a first energy ray curing resin. A hologram is copied by bringing the photosensitive material in contact with a master having a hologram record layer on which a hologram has been recorded and irradiating laser light from the first energy ray curing resin side to the photosensitive material and the master that have been brought into contact with each other. The photosensitive material and a second energy ray curing resin are adhered. The first energy ray curing resin and the second energy ray curing resin coated on the photosensitive material are cured.

It is preferred that a first position at which the coating step is performed, a second position at which the copying step is performed, a third position at which the curing step is performed, and a fourth position at which the curing step is performed be connected in line by conveying means.

According to an embodiment, a photosensitive material of a hologram record layer is coated on a support made of an energy ray curing resin. The support can be thinly formed by coating the energy ray curing resin. Thus, the support on which the photosensitive material is coated functions as a hard coat and is formed as a surface protection layer.

According to an embodiment, a surface protection layer coated on a hologram record layer is made by thinly coating an energy ray curing resin on a release paper. An adhesive agent layer is also coated on the hologram record layer. Since the adhesive agent layer is black, it is not necessary to use a black sheet since the background in which the hologram laminate is adhered to a product does not prevent the user from viewing a hologram.

The surface protection layer made of an energy ray curing resin and the blocking layer has nearly no birefringence. In addition, a resin material having the same refractive index as that of the photosensitive material can be easily used. When an energy ray curing resin layer is used as a support instead of a commonly used resin film, the total thickness of the hologram laminate can be decreased, the production cost can be reduced, and the refractive indexes of the individual structural layers can be uniformed.

When a hologram is copied by laser exposure, a wet photosensitive material is brought into contact with the front surface of a hologram master without use of an optical contact liquid. Thus, air can be removed from the boundary between the hologram master and the hologram laminate.

Since a resin film is not used as a structural element of the hologram laminate, if the hologram laminate is peeled off from a product, since the energy ray curing resin layer that is not rigid is destroyed, it is difficult to adhere the hologram laminate to the product again. Thus, the security can be improved.

These and other objects, features and advantages will become more apparent in light of the following detailed description and as illustrated in the accompanying drawings.

Additional features and advantages are described herein, and will be apparent from the following Detailed Description and the figures.

### BRIEF DESCRIPTION OF THE FIGURES

FIG. 1 is a sectional view showing the structure of a hologram laminate of the related art;

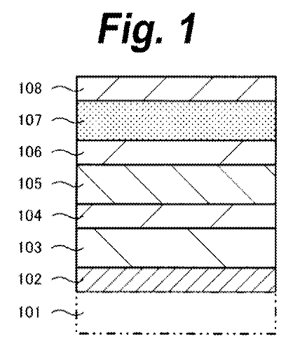

FIG. 2 is a schematic diagram describing an example of an imaging process performed when a holographic stereogram is produced;

FIG. 3A and FIG. 3B are schematic diagrams showing an example of an optical system of a holographic stereogram printer device;

FIG. 4A and FIG. 4C are schematic diagrams showing a photosensitive process for an optically curing photopolymer;

FIG. 5 is a sectional view showing a hologram laminate according to an embodiment;

FIG. 6 is a sectional view showing a hologram laminate according to a modification of the embodiment;

FIG. 7A to FIG. 7D are sectional views showing laminate structures of individual steps of a hologram production method according to an embodiment;

FIG. 8 is a schematic diagram showing coating, drying, and film thickness control steps for a photosensitive material in the hologram production method;

FIG. 9 is a schematic diagram showing copying, adhering, and ultraviolet-ray-curing-resin curing steps in the hologram production method;

FIG. 10 is a schematic diagram showing external appearance, cut-out and winding steps of the hologram production method;

FIG. 11A to FIG. 11D are schematic diagrams describing a copying step of a copying device;

FIG. 12 is a schematic diagram describing an example of a structure in which a hologram laminate has been laminated; and

FIG. 13 is a schematic diagram describing another example in which a hologram laminate has been laminated.

### DETAILED DESCRIPTION

Next, with reference to the accompanying drawings, embodiments will be described. The description will be made in the following order.

1. One embodiment

2. Another embodiment (modification)

### 1. One Embodiment

### [Hologram Master Production System]

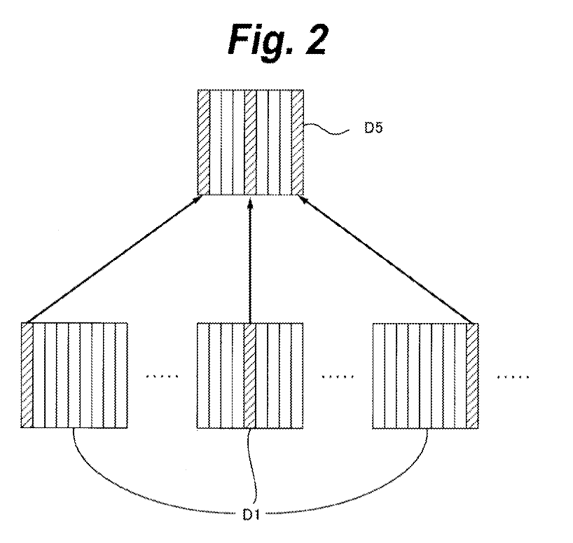

First, a master on which a hologram has been recorded is produced. The master is produced by successively recording a plurality of rectangular hologram elements having, for example, horizontal parallax information on one hologram record medium. In other words, as shown in FIG. 2, each of a plurality of pieces of image data containing parallax information is divided in the parallax direction, namely horizontal (width) direction, slices are obtained, and the divided slices are collected to form a processed image D5.

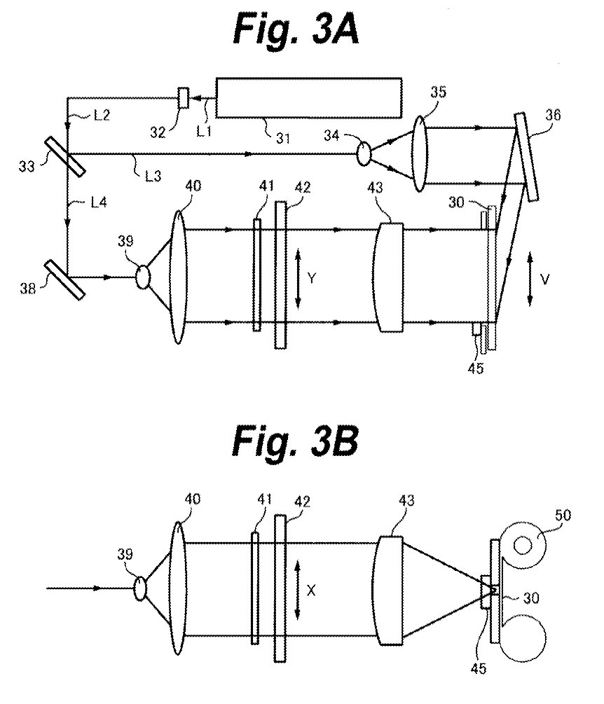

Next, with reference to FIG. 3A and FIG. 3B, an optical system of the printer device that produces such a master will be described in detail. FIG. 3A is a top view of the optical system of the entire printer device and FIG. 3B is a side view showing the optical system of the entire printer device.

As shown in FIG. 3A and FIG. 3B, the printer device includes a laser light source 31 that emits laser light having a predetermined wavelength, a shutter 32 disposed on the optical axis of laser light L1 emitted from the laser light source 31, a mirror 38, and a half mirror 33. In this embodiment, as the laser light source 31, an argon laser that has a wavelength of 514.5 nm and an output of 200 mW is used.

The shutter 32 is controlled by a controlling computer. The shutter 32 is closed when a hologram record medium 30 is not exposed. The shutter 32 is opened when the hologram record medium 30 is exposed. In addition, the half mirror 33 separates laser light L2 that passes through the shutter 32 into reference light and object illumination light. Light L3 reflected by the half mirror 33 becomes reference light and light L4 that passes through the half mirror 33 becomes object illumination light.

In this optical system, the optical path length of reference light that is reflected by the half mirror 33 and that enters the hologram record medium 30 is nearly the same as that of the object illumination light that passes through the half mirror 33 and that enters the hologram record medium 30. Thus, since coherency between the reference light and the object illumination light increases, a hologram that reproduces a more clear reproduction image can be produced.

As an optical system for the reference light, a cylindrical lens 34, a collimator lens 35 that collimates reference light, and a total reflection mirror 36 that reflects collimated light that passes through the collimator lens 35 are disposed in this order on the optical axis of light L3 reflected by the half mirror 33.

The cylindrical lens 34 diverges light reflected by the half mirror 33. Thereafter, the diverged light is collimated by the collimator lens 35. Thereafter, the collimated light is reflected by the total reflection mirror 36. The reflected light enters the rear surface of the hologram record medium 30.

On the other hand, as an optical system for object illumination light, a totally reflection mirror 38 that reflects light that has transmits through the half mirror 33, a spatial filter 39 made of a combination of a convex lens and a pin hole, a collimate lens 40 that collimates object illumination light, a display device 41 that displays an image to be recorded, a one-dimensional diffusion plate 42 that diffuses light that transmits through the display device 41 in the width direction of hologram elements, a cylindrical lens 43 that collects the object illumination light that transmits through the one-dimensional diffusion plate 42 on the hologram record medium 30, and an optical functional plate 45 that has a one-dimensional diffusion function are disposed in this order on the optical axis of light L4 that transmits through the half mirror 33.

The cylindrical lens 43 collects object illumination light in the parallax direction (short-side direction of hologram elements or horizontal direction in observation). The optical functional plate 45 one-dimensionally diffuses collected object illumination light in the long-side direction of the rectangular hologram elements corresponding to movement of the viewpoint in the long-side direction. For example, a fine-pitched lenticular lens can be used as the optical functional plate 45.

Light L4 that has transmitted through the half mirror 33 is reflected by the total reflection mirror 38 to the spatial filter 39. The spatial filter 39 diffuses the light reflected by the total reflection mirror 38 as a light emitted from a point light source. Thereafter, the collimate lens 40 collimates the diffused light. The diffused light enters the display device 41. The display device 41 is a projection type image display device composed of a liquid crystal display. The display device 41 is controlled by the controlling computer to display an image based on image data D5 sent from the controlling computer.

Light that has transmitted through the display device 41 is modulated with an image displayed on the display device 41 and diffused by the one-dimensional diffusion plate 42. The one-dimensional diffusion plate 42 slightly diffuses light that has transmitted through the display device 41 in the width direction of the hologram elements and disperses light in the hologram elements so as to contribute improvement of image quality of the produced hologram.

The one-dimensional diffusion plate 42 has a diffusion plate moving section (not shown). Whenever each hologram element is formed, the diffusion plate moving section randomly moves the hologram element so as to reduce noise that is present at infinity when the user observes the hologram.

### [Hologram Record Medium]

Next, the hologram record medium 30 that is used in the foregoing hologram master production system will be described. The hologram record medium 30 has a structure in which a photopolymer layer is sandwiched with glass plates or a structure in which a photopolymer is coated on a film.

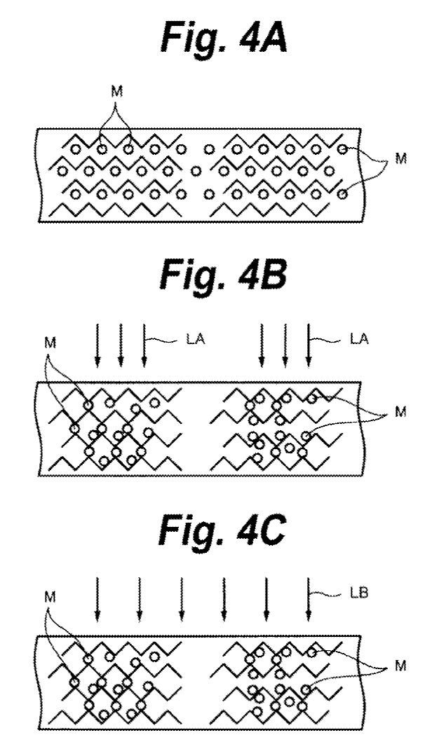

As shown in FIG. 4A, initially in a photopolymerizing type photopolymer, monomer molecules M are equally dispersed in a matrix polymer. However, as shown in FIG. 4B, when light La having a power of around 10 to 400 mJ/cm² is irradiated to the photopolymer, monomer particles M are polymerized at the exposed portion. As the monomer particles M are further polymerized, they are moved to the exposed region. Thus, the concentration of monomer particles M varies by location. As a result, refractive index modulation occurs. Thereafter, as shown in FIG. 4C, when ultraviolet light or visible light LB having a power of around 1000 mJ/cm² is irradiated on the entire surface of the photopolymer, monomer particles M are completely polymerized. Since the refractive index of the optically curing photopolymer varies with incident light, interference fringes (brightness and darkness) that occur due to interference between reference light and object illumination light can be recorded as changes of the refractive index.

### [Hologram Laminate]

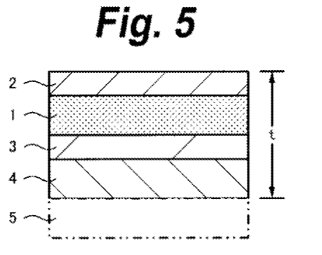

The master is produced by the foregoing printer device. A hologram laminate of the embodiment is closely brought into contact with the master and irradiated with laser light. As a result, a copy is produced from the master. The hologram laminate has a structure shown in FIG. 5.

The hologram laminate according to this embodiment includes a hologram record layer 1 made of a photosensitive material, a surface protection layer (referred to as a hard coat) 2 coated on the upper surface of the hologram record layer 1, and a blocking layer (referred to as a hard coat) 3 coated on the lower surface of the hologram record layer 1. The hard coats 2 and 3 are made of an energy ray curing resin, for example, an ultraviolet ray curing resin. The ultraviolet ray curing resins of the hard coats 2 and 3 may be either in fully cured state or half cured state. When the hologram laminate is formed as a seat, a separator layer (a release film made of a resin such as PET) 5 is formed on the lower surface of the hard coat 3 through an adhesive agent layer (also referred to as an adhesion layer).

The hologram record layer 1 is made of a photosensitive material, for example, a photopolymer having a refractive index N of 1.52 and can record brightness and darkness of incident light as the changes of the refractive index. Characteristics necessary for the hologram record layer 1 are as follows.

High diffraction efficiency (for example, 90% or higher), full width at half maximum of diffraction wavelength: 5 to 30 nm, high sensitivity (for example, 20 mJ/cm² or less), and low shrinkage ratio.

The hard coat 2 is formed so as to prevent scratching and electric charging, form film shape, and stabilize hologram shape. Characteristics necessary for the hard coat 2 are as follows:

High surface hardness (preventing scratching), low surface resistance, heat resistance (for example, 100 to 120° C.), low humidity absorption, high adhesiveness and material contact, optical refractive index close to that of photosensitive material (for example, 1.52), low birefringence (for example, ±15 nm (at a wavelength of 633 nm)), low haze (degree of unclearness (appearance) of front surface or inside), high transparency, high surface smoothness, and thin film thickness (for example, 20 μm or less).

The hard coat 3 is formed to prevent light from transmitting through the material and stabilize hologram shape. Since a photosensitive material chemically reacts with a resin film of the separator layer 5, the hard coat 3 is formed as a blocking layer. Characteristics necessary for the hard coat 3 are as follows:

Solvent resistance (to prevent the hard coat 3 from being chemically damaged by a solvent of a photosensitive material), heat resistance (for example, 100 to 120° C.), low moisture absorption, good adhesiveness and material contact, and thin film thickness (for example, 20 μm or less).

A characteristic necessary for the adhesive agent layer 4 is good adhesiveness. The adhesive agent layer 4 is black such that the background in which the hologram laminate is adhered to a product does not prevent the user from viewing a hologram.

Thicknesses of these layers are for example:
Hologram record layer: 12 μm, hard coat 2: 10 μm, hard coat 3: 10 μm, adhesive agent layer 4: 17 μm,

Total thickness t of hologram laminate: 49 μm

The thickness of the hologram laminate according to this embodiment can be decreased to 50 μm or less in comparison with the thickness of the hologram laminate of the related art, which is 100 μm or more.

In the structure of the hologram laminate according to this embodiment shown in FIG. 5, if it is likely that the photosensitive material of the hologram record layer 1 chemically reacts with the adhesive agent layer 4, the hard coat 3 is necessary. If not, the hard coat 3 may be omitted. In other words, as shown in FIG. 5, the hologram laminate may be made of the hologram record layer 1 and the hard coat 2 coated on the upper surface of the hologram record layer 1. In this structure, the thickness of the hologram laminate can be further decreased.

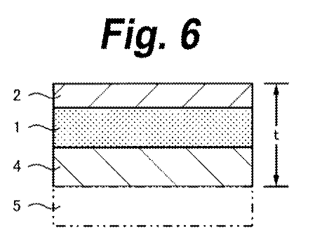

The thicknesses of the individual layers of the hologram laminate shown in FIG. 6 are as follows: Hologram record layer: 12 μm, hard coat 2: 10 μm, adhesive agent layer: 17 μm,

Total thickness t of hologram laminate: 39 μm

### [Production Method of Hologram Laminate]

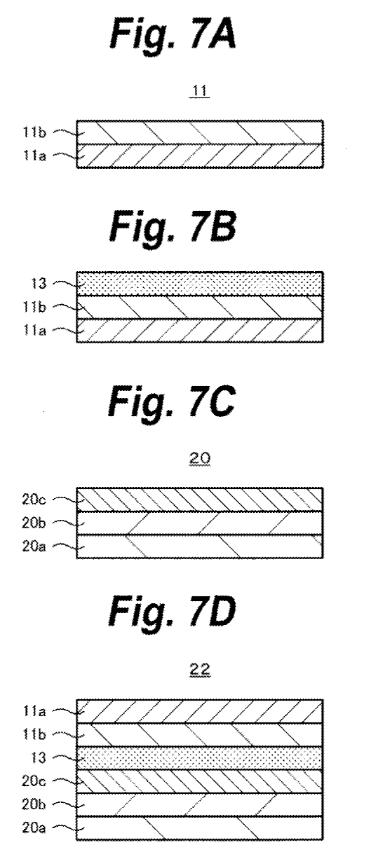

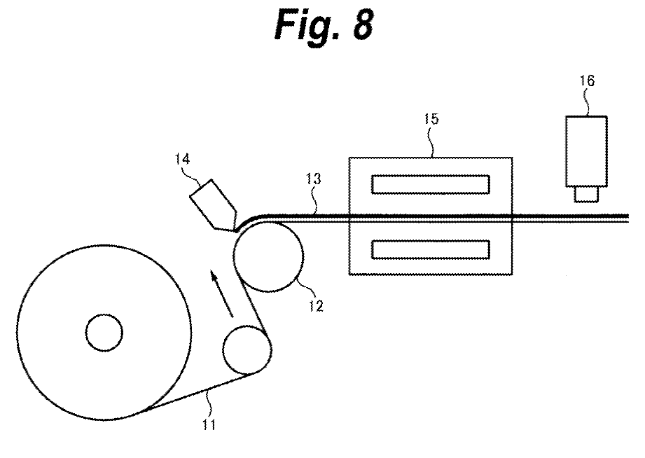

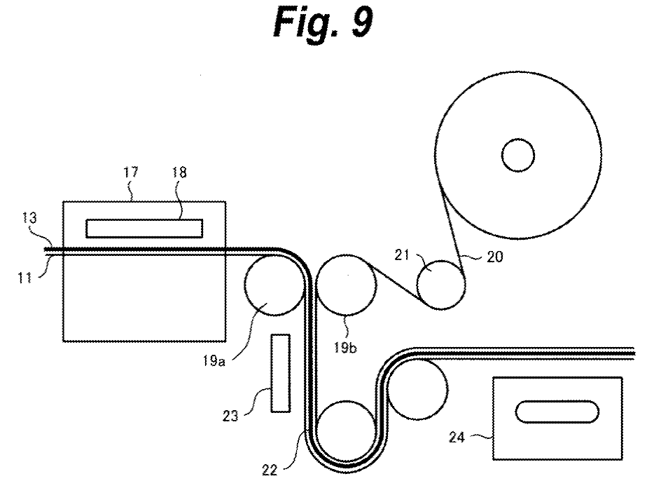

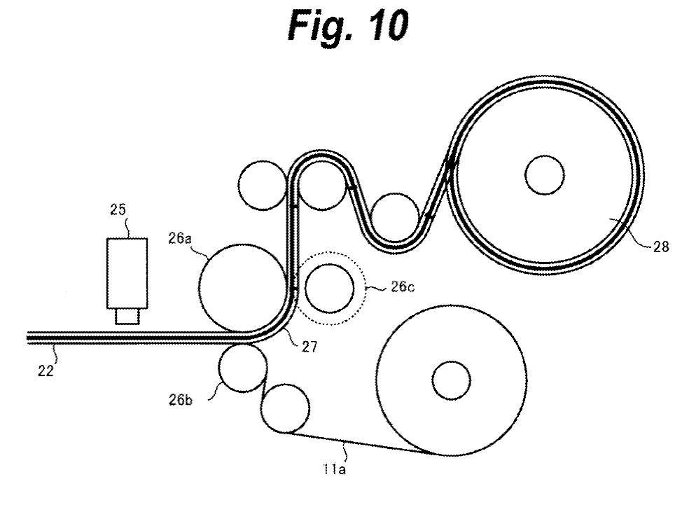

Next, with reference to FIG. 7A to FIG. 7D, FIG. 8, FIG. 9, and FIG. 10, production steps of the foregoing hologram laminate will be described. FIG. 7A to FIG. 7D show laminate structures at the individual steps. Although FIG. 8, FIG. 9, and FIG. 10 show a series of productions steps, they are separated because of limited drawing space.

FIG. 8 shows a coating step, a drying step, and a film thickness control step for a photosensitive material. As shown in FIG. 7A, a film 11 in which an energy ray curing resin, for example an ultraviolet ray curing resin 11b, that composes the hard coat 2 has been coated on a release film 11a made, for example, of PET is wound in a roll shape. The ultraviolet ray curing resin 11b is in a non-cured state or a semi-cured state (this state is referred to as the wet state). The release film 11a reinforces the tensile strength of the ultraviolet ray curing resin 11b. As will be described later, after the hologram laminate is produced, the release film 11a is peeled off and disposed of.

The film 11 that is fed is traveled in the arrow direction and wound on the circumferential surface of a roller 12. A photosensitive material, for example, a photopolymer 13, is coated on the ultraviolet ray curing resin 11b of the film 11 by a slit die head 14 such that the photopolymer 13 has a predetermined film thickness. The slit die head 14 coats a liquid photopolymer containing an organic solvent on the ultraviolet ray curing resin 11b with the width of the slit. The liquid photopolymer is supplied from a tank (not shown). The opening/closing and width of the slit can be controlled by a control section (not shown).

The film 11 on which the photopolymer 13 has been coated is introduced to a drying section 15. The drying section 15 dries the film 11 so as to remove the organic solvent. In other words, the drying section 15, for example, irradiates far infrared ray or blows warm air to the photopolymer 13 so as to dry the photopolymer 13 and prevent it from dripping. After the photopolymer 13 is dried, it becomes in the wet state.

After the photopolymer 13 is dried, the thickness is measured by a film thickness measurement device 16. The opening ratio and so forth of the slit of the slit die head 14 are controlled based on the measured result such that the thickness of the photopolymer 13 becomes constant. FIG. 7B shows the structure of the laminate on which the photopolymer 13 has been coated.

Next, with the structure shown in FIG. 9, copying, adhering, and ultraviolet-ray-curing-resin curing steps are performed. A three-layer film in which the photopolymer 13 has been coated on the laminate film of the release film 11a and the ultraviolet ray curing resin 11b is introduced to a copying device 17. In the copying device 17, the photopolymer 13 is brought into contact with a master 18 while the travelling of the film 11 is stopped. Thereafter, laser light is irradiated to the photopolymer 13. In the foregoing theory described with reference to FIG. 4A to FIG. 4C, interference fringes of the master 18 are copied as changes of the refractive index to the photopolymer 13. The copying device 17 will be described later in detail.

The film 11 having the photopolymer 13 in which the interference fringes have been copied is introduced between rollers 19a and 19b that rotate while they are in contact with each other. On the other hand, the roll-shaped film 20 is fed and introduced between the rollers 19a and 19b through a roller 21. As shown in FIG. 7C, the film 20 has a structure in which an ultraviolet ray curing resin 20c corresponding to the hard coat 3 has been laminated on a PET separator layer 20a (corresponding to the separator layer 5 shown in FIG. 2) through a black adhesive agent layer 20b (corresponding to the adhesive agent layer 4 shown in FIG. 2). The ultraviolet ray curing resin 20c is in the wet state. When the hologram laminate shown in FIG. 6 is produced, the ultraviolet ray curing resin 20c is omitted from the film 20.

The rollers 19a and 19b oppositely press the photopolymer 13 and the ultraviolet ray curing resin 20c each other and adhere them. The adhered film is denoted by reference numeral 22. When necessary, the film 22 is dried by a drying section 23. An ultraviolet ray irradiation device 24 irradiates ultraviolet ray to the film 22 that has passed through the drying section 23. The film 22 has a laminate structure shown in FIG. 7D.

Irradiation of ultraviolet ray causes the ultraviolet ray curing resins 11b and 20c to become in the semi-cured state or fully cured state. They become the hard coats 2 and 3 that satisfy the foregoing necessary characteristics. The laminate shown in FIG. 7D basically has the structure of the hologram laminate according to the embodiment shown in FIG. 2 except for the release film 11a.

The film 22 is conveyed to a visual inspection, cut-out, and winding steps shown in FIG. 10. A defect inspection camera 25 inspects whether or not the film 22 has a defect. The film 22 is inserted into rollers 26a and 26b that rotate while they are in contact with each other. The release film 11a is peeled off and wound in a roll shape. A film 27 from which the release film 11a has been peeled off is basically a hologram laminate.

The film 27 is inserted into the roller 26a and a cut-out roll cutter 26c that rotate while they are in contact with each other so as to cut out the film 27. As a result, the film 27 is cut out with the depth from the ultraviolet ray curing resin 11b corresponding to the surface protection hard coat 2 to, for example, the front surface of the separator layer 20a. The cut-out roll cutter 26c forms desired plane cuts of the film 27 by moving the width of the film 27 or forming square cuts. Unnecessary portions of the film 27 that have been cut out may be disposed of.

The film 27 that has been cut out is wound on a product winding roll 28. The film 27 (film-shaped hologram laminate) having a predetermined length is wound on each roll. After the foregoing steps are completed, the hologram laminate is obtained. The series of production steps described with reference to FIG. 8, FIG. 9, and FIG. 10 are performed in line. Since the series of production steps are performed in line, a decrease of the yield due to deterioration of the photosensitive material and adhesion of foreign matter can be prevented. In addition, a darkroom storage space for non-exposed materials can be omitted.

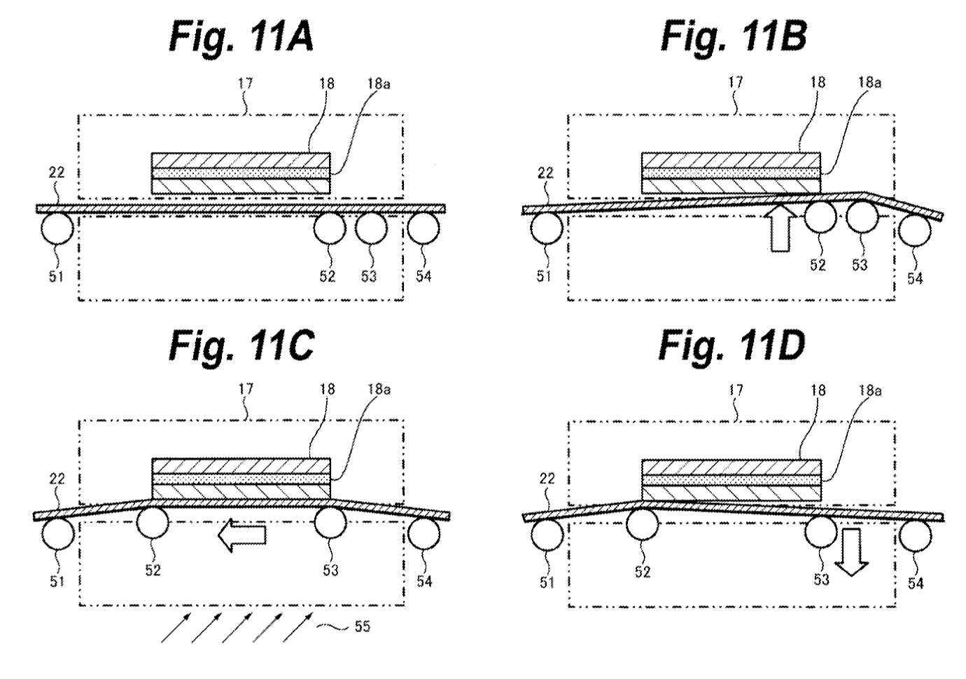

Next, with reference to FIG. 11A to 11D, the foregoing copying device 17 (see FIG. 9) will be described in detail. The copying device 17 includes a chamber (denoted by a two-dot line) that seals a copying area including the master, an exhaust device (not shown) that provides a vacuum environment for the entire chamber, and rollers 51, 52, 53, and 54 each having a width larger than the width of the master 18. The master 18 is formed, for example, of two glass plates and a recorded hologram record layer 18a sandwiched therewith. The master 18 may be a film type having the same structure as that of the hologram laminate according to the embodiment. The exposed surface of the photopolymer 13 of the film 22 faces the upper surface of the master 18. The rollers 51 to 54 are disposed on the lower surface side of the film 22.

The rollers 51 and 54 are fixedly disposed on the entrance side and the exit side of the copying device 17, respectively. The rollers 52 and 53 are disposed in the vicinity of the exit side of the copying device 17. The roller 52 is disposed below the edge of the exit side of the master 18. The rollers 52 and 53 can be moved in the vertical direction. The rollers 52 and 53 can be slid in the reverse direction of the traveling direction of the film 22 (from left to right viewed from the top of FIG. 11A to FIG. 11D).

As shown in FIG. 11A, when the copy region of the film 22 is positioned below the master 18, traveling of the film 22 is stopped and the chamber is vacuumed. This is because air is prevented from entering the boundary between the master 18 and the photopolymer 13 of the film 22. However, the vacuum step may be omitted.

Thereafter, as shown in FIG. 11B, the rollers 52 and 53 are raised, causing the film 22 to be lifted up. The rollers 52 and 53 are raised to a position slightly higher than the position at which the film 22 contacts the edge of the master 18. Thus, the photopolymer 13 of the film 22 is brought into contact with the edge of the master 18.

Thereafter, as shown in FIG. 11C, the rollers 52 and 53 are slid such that the film 22 is pressed to the edge of the exit side of the master 18 by the roller 53 and the roller 52 is slid to the position below the edge of the entrance side of the master 18. When the rollers 52 and 53 are slid, the roller 52 causes the photopolymer 13 of the film 22 to press the master 18. As described above, since the photopolymer 13 is in the wet state, the photopolymer 13 and the master 18 fully contact each other free from air therebetween without necessity of using a contact liquid. Laser light 55 is irradiated to the photopolymer 13 while it contacts the master 18. The wavelength of laser light with which the hologram is copied to the photopolymer 13 is the same as that with which the hologram is recorded to the master 18.

When a predetermined amount of the laser light 55 is irradiated to the photopolymer 13 for a predetermined period, brightness and darkness due to interference between reflected light (object illumination light) from the hologram record layer 18a of the master 18 and the laser light 55 (reference light) are recorded as changes of the refractive index on the photopolymer 13. After irradiation of the laser light 55, ultraviolet ray may be irradiated so as to fully cure the ultraviolet ray curing resin.

Thereafter, as shown in FIG. 11D, air is introduced, the exit side roller 53 is lowered, and the film 22 is peeled off from the master 18 at the edge of the exit side of the master 18. After the film 22 is peeled off from the master 18, the rollers 52 and 53 are slid, lowered, and placed at their initial positions shown in FIG. 11A. Thereafter, the film is conveyed and stopped at the position where the next record region is present on the lower surface of the master 18. Thereafter, the foregoing copying step is performed.

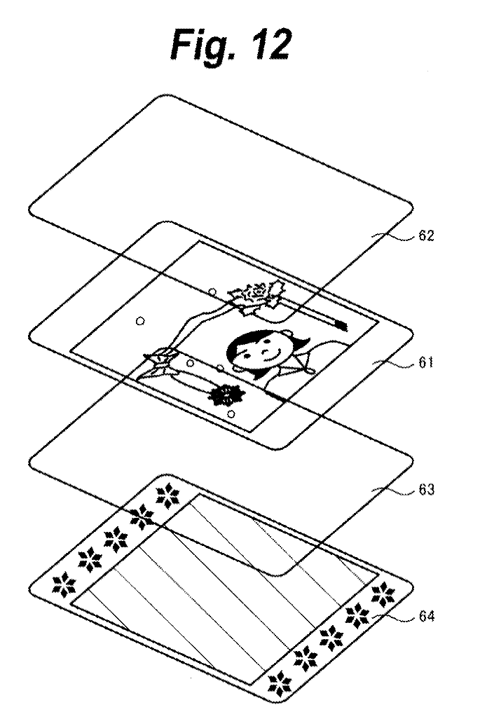

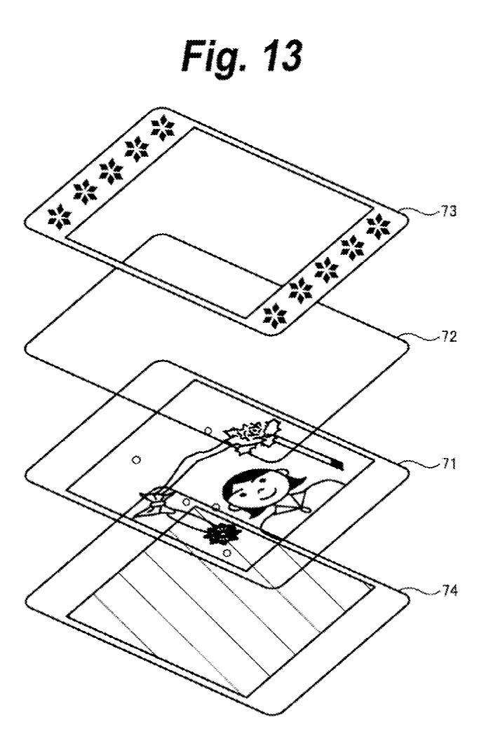

According to the foregoing embodiment, the hologram laminate is coated on the separator layer 5 through the adhesive agent layer. However, in the case of a card type hologram, since it is laminated, the separator layer 5 may not be used. FIG. 12 and FIG. 13 show examples of structures of ruminated holograms that do not use the separator layer 5.

In FIG. 12, reference numeral 61 represents a hologram laminate according to an embodiment. In other words, the hologram laminate 61 has a laminate structure of a hologram record layer 1 on which image information has been recorded and hard coats 2 and 3 coated on surfaces of the hologram record layer 1. The hologram laminate 61 is coated on its surfaces with transparent resin films 62 and 63 made of PET or the like.

In addition, a print film 64 is formed on the lower surface of the transparent resin film 63. The print film 64 is a resin film in which an image is printed on a frame of the print film 64 and the rear surface thereof is printed in black. These hologram laminate 61, the transparent resin films 62 and 63, and the print film 64 have a similar shape and mutually adhered by a method such as heat adhesion.

The other example shown in FIG. 13 has a laminate structure in which a transparent resin film 72 and a print film 73 are successively laminated on the upper surface of a hologram laminate 71 and a white resin (FET) film 74 is laminated on the lower surface of the hologram laminate 71. Text, an image, or the like is printed on the frame of the print film 73 and the inside of the frame is transparent. A surface on which the resin film 74 contacts the hologram laminate 71 is printed in black. Text or the like is printed on the reverse surface of the resin film 74. Letters and so forth of the text printed on the reverse surface describe, for example, how to use the hologram.

### 2. Other Embodiment

When a pretreatment such as corona discharge is performed for the front surface of an energy ray curing resin on which a photosensitive material is coated, adhesiveness between the energy ray curing resin and the photosensitive material is improved. Moreover, in the foregoing description, although an ultraviolet ray curing resin was used, an electron beam curing resin, a visible light curing resin, a thermally curing resin, or the like may be used.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A hologram laminate, comprising:
a hologram record layer including a photosensitive material; and
a surface protection layer coated on one surface of the hologram record layer,
wherein the surface protection layer includes an energy ray curing resin.

2. The hologram laminate as set forth in claim 1,
wherein an adhesive agent layer is coated on another surface of the hologram record layer.

3. The hologram laminate as set forth in claim 2,
wherein the adhesive agent layer is black.

4. The hologram laminate as set forth in claim 3,
wherein a separator layer is coated on the adhesive agent layer.

5. A hologram laminate, comprising:
a hologram record layer including a photosensitive material;
a surface protection layer coated on one surface of the hologram record layer, and
a blocking layer coated on another surface of the hologram record layer,
wherein the surface protection layer and the blocking layer include an energy ray curing resin.

6. The hologram laminate as set forth in claim 5,
wherein an adhesive agent layer is further coated on the blocking layer.

7. The hologram laminate as set forth in claim 6,
wherein the adhesive agent layer is black.

8. The hologram laminate as set forth in claim 6,
wherein a separator layer is coated on the adhesive agent layer.

9. A method of copying a hologram, the method comprising:
coating a photosensitive material on an energy ray curing resin;
oppositely placing the photosensitive material and a master having a hologram record layer on which a hologram has been recorded;
bringing the photosensitive material into contact with the master; and
irradiating laser light from the energy ray curing resin side to the photosensitive material and the master that have been brought into contact with each other.

10. A method of copying a hologram, the method comprising:
coating a photosensitive material having a predetermined thickness on an energy ray curing resin;
copying a hologram by bringing the photosensitive material in contact with a master having a hologram record layer on which a hologram has been recorded and irradiating laser light from the energy ray curing resin side to the photosensitive material and the master that have been brought into contact with each other, and
curing the energy ray curing resin coated on the photosensitive material.

11. The method as set forth in claim 10,
wherein a first position at which the coating step is performed, a second position at which the copying step is performed, and a third position at which the curing step is performed are connected in line by conveying means.

12. A method of copying a hologram, the method comprising:
coating a photosensitive material having a predetermined thickness on a first energy ray curing resin;
copying a hologram by bringing the photosensitive material in contact with a master having a hologram record layer on which a hologram has been recorded and irradiating laser light from the first energy ray curing resin side to the photosensitive material and the master that have been brought into contact with each other;
adhering the photosensitive material and a second energy ray curing resin; and
curing the first energy ray curing resin and the second energy ray curing resin coated on the photosensitive material.

13. The method as set forth in claim 12,
wherein a first position at which the coating step is performed, a second position at which the copying step is performed, a third position at which the curing step is performed, and a fourth position at which the curing step is performed are connected in line by conveying means.
